(19) United States
(12) Patent Application Publication
(10) Pub. No.: US 2015/0364704 A1
(43) Pub. Date: Dec. 17, 2015

(54) PHOSPHORESCENT EMITTING COMPOSITIONS

(71) Applicant: R-Display & Lighting LLC, Webster, NY (US)

(72) Inventor: Tommie L. ROYSTER, Webster, NY (US)

(73) Assignee: R-Display & Lighting LLC, Webster, NY (US)

(21) Appl. No.: 14/737,136

(22) Filed: Jun. 11, 2015

Related U.S. Application Data
(60) Provisional application No. 62/010,569, filed on Jun. 11, 2014.

(51) Int. Cl. H01L 51/00; C07F 15/00; C09K 11/06

(52) U.S. Cl. CPC H01L 51/0087; C09K 11/06; C07F 15/0093; C09K 2211/185; H01L 51/5016

(57) ABSTRACT

A light emitting composition comprising a central platinum group transition metal and a bidentate ligand of novel structure for transition metal complexes forming a six membered ring. The platinum group transition metal may be selected from the group consisting of platinum, palladium, iridium, rhodium, ruthenium, and osmium. Additionally, OLED devices are disclosed, each of the OLED devices comprising a light emitting layer that includes one of the light emitting compositions.

### CROSS-REFERENCE TO RELATED PATENT APPLICATIONS

This application claims priority to U.S. Provisional Patent Application No. 62/010,569, filed Jun. 11, 2014, the disclosure of which is incorporated herein by reference.

### BACKGROUND

1. Technical Field

Light-emitting compositions of matter. In particular, highly efficient phosphorescent emitter compositions that are useful in organic light emitting diodes.

2. Description of Related Art

Organic Light Emitting Diode (OLED) devices are based on strategic placement of organic thin films between electrodes (i.e. an anode and a cathode). The basic structure of an OLED device is shown in FIG. 1. Injection of holes and elections from the anode and cathode result in light emission through recombination of the holes and electrons in the light emitting layer of the “organic stack,” which is the set of layers between the anode and the cathode. The organic thin films in an OLED device are typically less than 50 nanometers (nm) in thickness, resulting in low voltage operations and potential to produce low power consuming devices. These attributes are advantageous in the use of OLED devices in image display and lighting applications.

The excited states generated from hole and electron injection setup two pathways for light emission. Singlet and Triplet exciton decay yield fluorescent and phosphorescent light respectively. The ratio of Singlet to Triplet exciton formation is 1:3. Therefore, emissive layers comprised of fluorescent dopant and host materials for harvesting singlet excitons have a theoretical limit of 25% for converting excitons into light. However, phosphorescent systems can theoretically convert 100% of the excitons generated into light by harvesting Singlet excitons (after intersystem conversion) and Triplet excitons. Emissive layers are comprised of a host material and a phosphorescent dopant. Steps representing the hole/electron injection process, Triplet exciton formation and subsequent exciton decay to produce light are depicted in FIGS. 2-4.

The high efficiency of phosphorescent based OLED devices establishes a platform for manufacturing very low power consuming lighting and display applications. Based on the high efficiency, lower driving currents are required for light output, thereby establishing the potential for significant savings in power consumption. The shift from fluorescent based OLED devices to phosphorescent based devices in commercial applications has commenced. However, there are still problems that remain to be solved for broader application of phosphorescent based OLED devices to occur.

One significant problem is emitter material stability under “high current density” operations, which are required for general lighting applications. The stability of state-of-the-art phosphorescent emitters is based in part on the type of ligands that are used to form organometallic phosphorescent emitters. Currently used emitter materials known to the Applicant are comprised of bidentate cyclometalating ligands coordinated to transition metals forming a five membered ring. Two types of bonds are formed upon coordination: a charge balancing bond, typically a metal-carbon bond; and a neutral donor-acceptor or dative metal-nitrogen bond.

Calculations from at least two independent studies predict the neutral metal-nitrogen bond in cyclometalated complexes ruptures upon absorption of high energy light or thermal activation in the Triplet excited state. Although the energy associated with red and green exciton formation would have a lower probability of inducing bond rupture of the metal-nitrogen bond in cyclometalated complexes relative to blue light, under high current density operation, the potential of bond rupture increases due to several mechanisms, including thermally activated processes.

Regardless of the degradation mechanism, present OLED phosphorescent emitter materials lack the desired stability that would enable broader adaptation of these materials in lighting and image display applications, at an acceptable lifetime and at a low cost. There remains a need for phosphorescent emitter materials that operate in an OLED device at high efficiency, and improved stability.

### SUMMARY

The present invention meets the stated need by providing phosphorescent emitter materials that provide high efficiency and enhanced metal-ligand bond stability, thereby enabling OLED devices that have high quantum efficiency and superior lifetimes.

More particularly, in accordance with the present disclosure, a light emitting composition is provided comprising a central platinum group transition metal and a bidentate ligand comprised of at least one fused pyridyl group forming a six membered ring complex. The platinum group transition metal may be selected from the group consisting of platinum, palladium, iridium, rhodium, ruthenium, and osmium. Additionally, in accordance with the present disclosure, OLED devices are provided, each of the OLED devices comprising a light emitting layer that includes one of the light emitting compositions.

### BRIEF DESCRIPTION OF THE DRAWINGS

The present disclosure will be provided with reference to the following drawings, in which like numerals refer to like elements, and in which:

FIG. 1 is a schematic illustration of the layered structure of an organic light emitting diode;

FIG. 2 is a schematic illustration of the hole/electron injection process in the generation of light by an organic light emitting diode;

FIG. 3 is a schematic illustration of the triplet exciton formation process in the generation of light by an organic light emitting diode;

FIG. 4 is a schematic illustration of the subsequent exciton decay process in the generation of light by an organic light emitting diode;

FIG. 5A is an illustration of the chemical structure of a generic light-emitting composition of the present disclosure;

FIG. 5B is an illustration of light-emitting composition of the present disclosure comprised of platinum coordinated to a bidentate ligand class;

FIG. 6 is an illustration of the chemical structure of a first exemplary light-emitting composition of the present disclosure;

FIG. 7A is an illustration of the chemical structure of a second exemplary light-emitting composition of the present disclosure;

FIG. 7B-7F are illustrations of the chemical structures of alternative third, fourth, fifth, sixth, and seventh light-emitting compositions of the present disclosure;

FIG. 8 is a photoluminescence spectrum of a reference emitter material;

FIG. 9 is a photoluminescence spectrum of the exemplary emitter material composition of FIG. 6;

FIG. 10 is a photoluminescence spectrum of the exemplary emitter material composition of FIG. 7A; and

FIG. 11 is an electroluminescence spectrum of an OLED device comprised of the exemplary emitter composition of FIG. 6.

The present invention will be described in connection with certain preferred embodiments. However, it is to be understood that there is no intent to limit the invention to the embodiments described. On the contrary, the intent is to cover all alternatives, modifications, and equivalents as may be included within the spirit and scope of the invention as defined by the appended claims.

### DETAILED DESCRIPTION

For a general understanding of the present invention, reference is made to the drawings. The drawings are to be considered as depicting exemplary embodiments of the invention, and not to be considered as limiting the invention solely to the embodiments depicted.

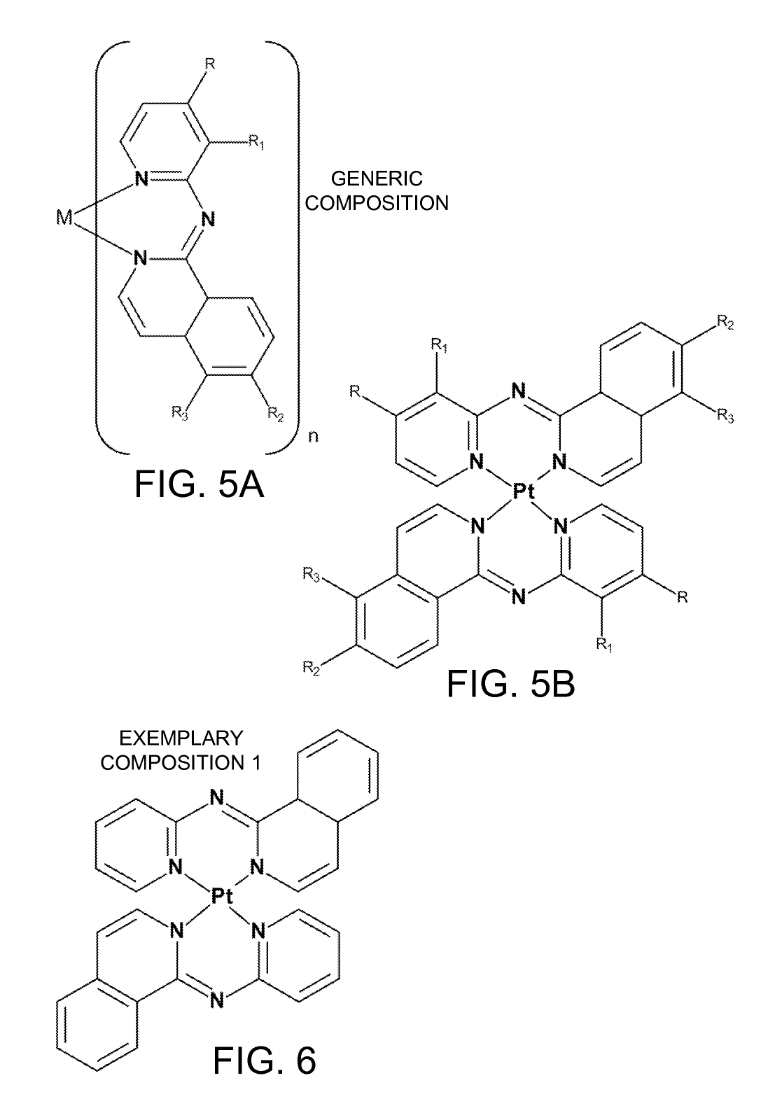

Through a combination of computational, synthetic and photoluminescence studies, the Applicant has discovered a new class of phosphorescent emitter material compositions that provide high efficiency and enhanced metal-ligand bond stability through unique molecular and electronic structures. The general structure of the new class of compositions is shown in FIG. 5A. The structure of the “generic composition” includes a central Platinum Group Transition Metal and bidentate ligand comprised of at least one fused pyridyl group forming a six membered ring complex. In various embodiments, n may be equal to 1, 2, or 3. The Platinum Group Transition Metal may be selected from platinum, palladium, iridium, rhodium, ruthenium, and osmium.

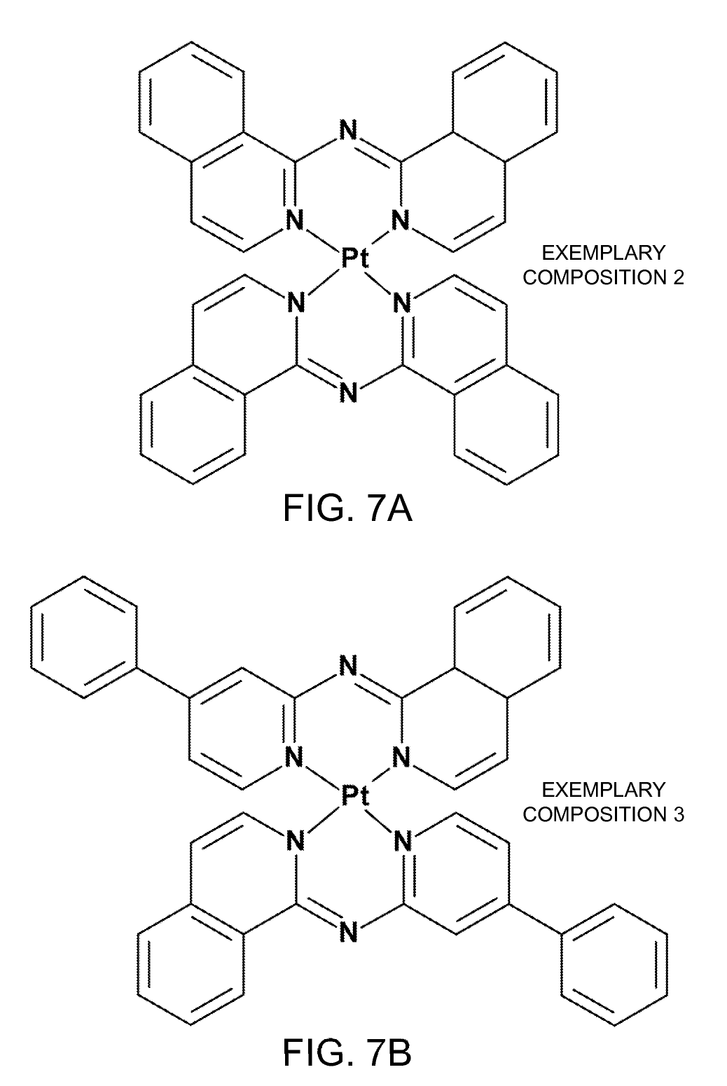

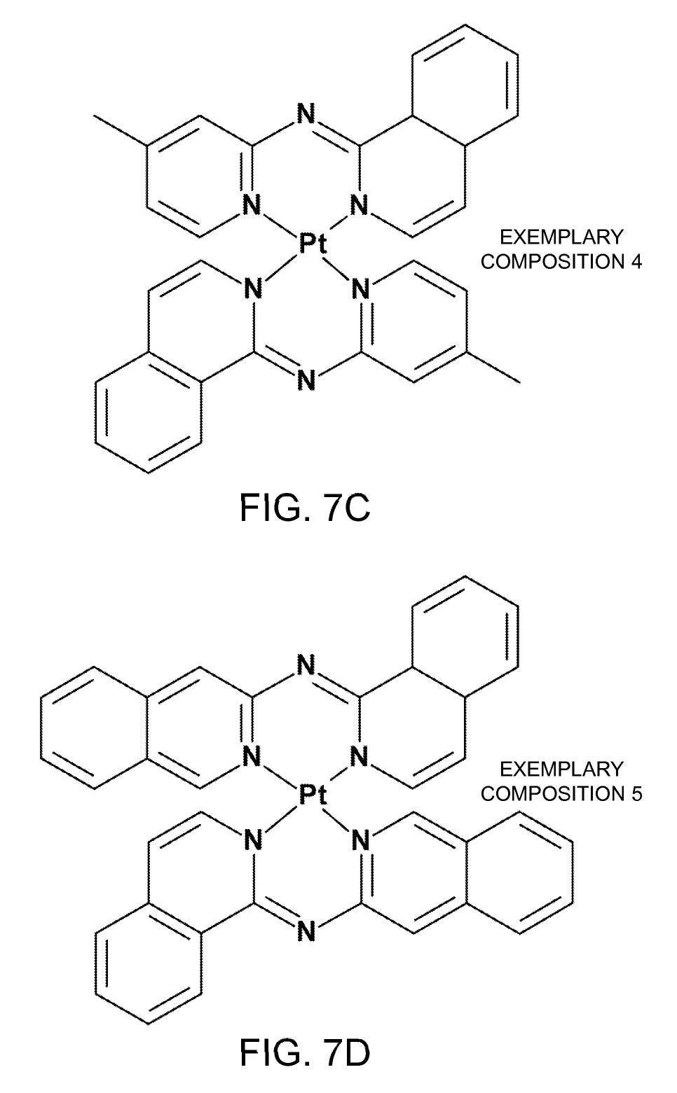

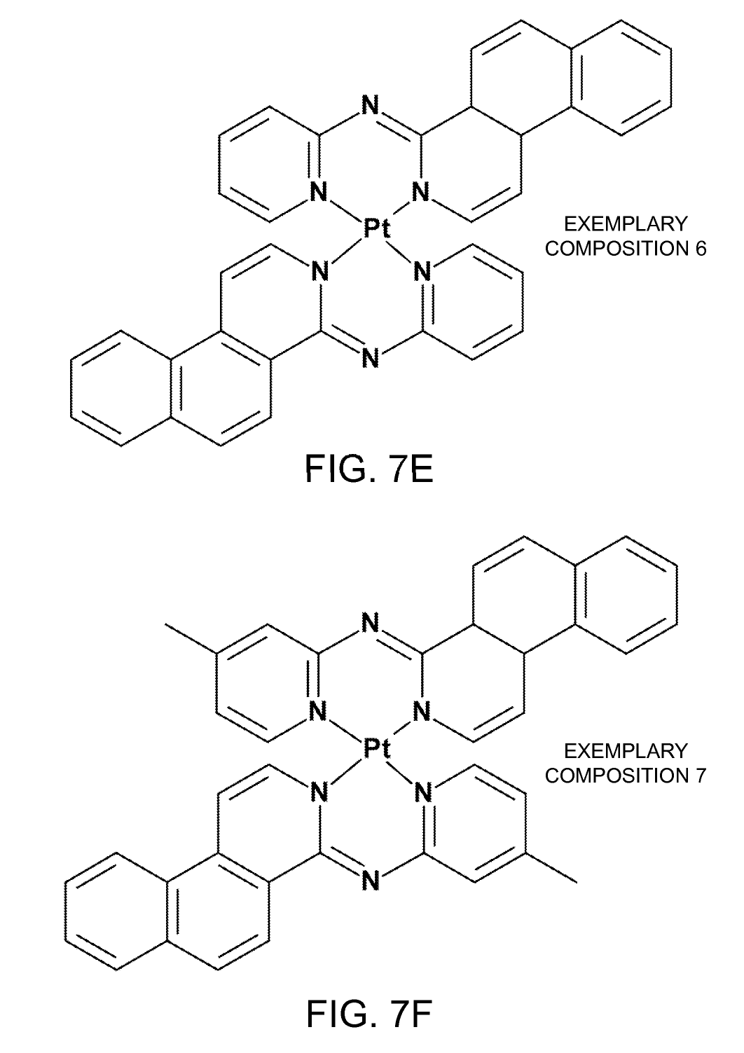

In various embodiments of the instant compositions, R, R₁, R₂, and R₃ may be independently of each other. In certain embodiments, R, R₁, R₂, and R₃ may be selected from hydrogen, an alkyl group, or an aryl group. Alternatively or additionally, in certain embodiments, R, R₁, R₂, and R₃ may be fused to form an aromatic ring. By way of illustration, and not limitation, Exemplary Composition 1 and Exemplary Composition 2 are shown in FIGS. 6 and 7A.

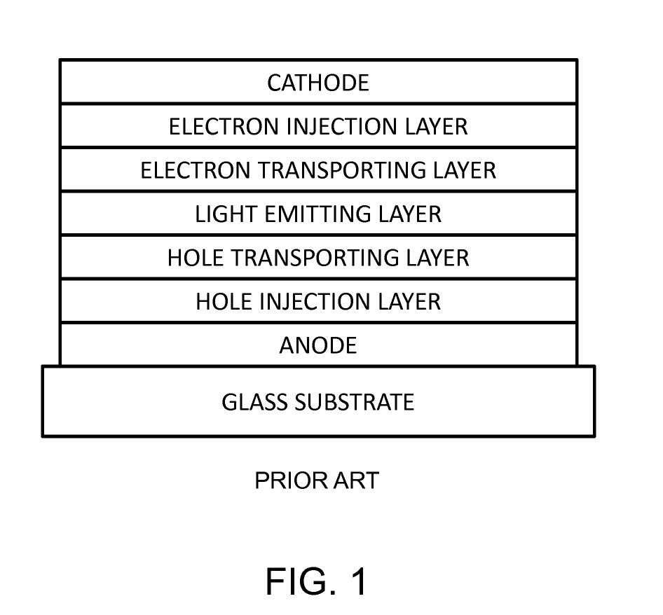

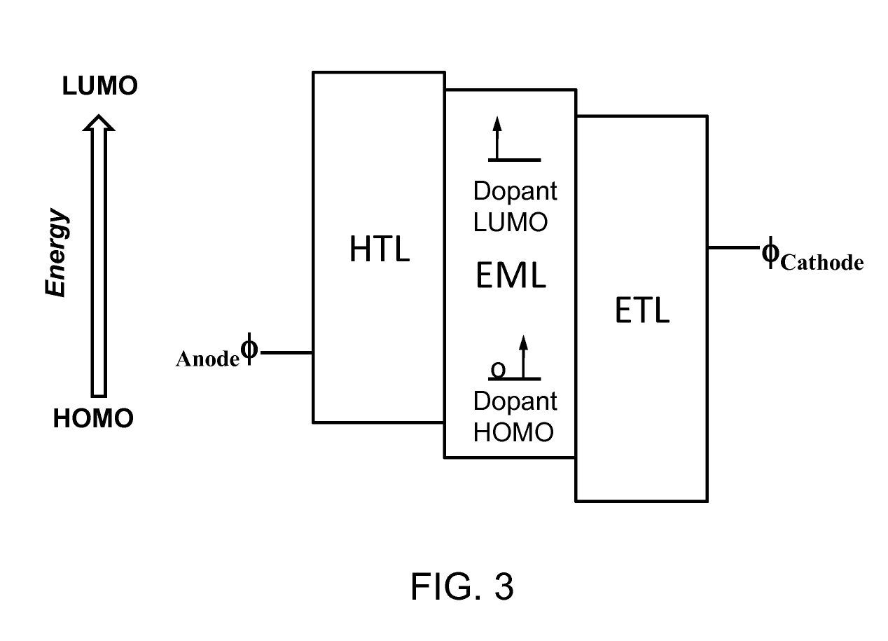

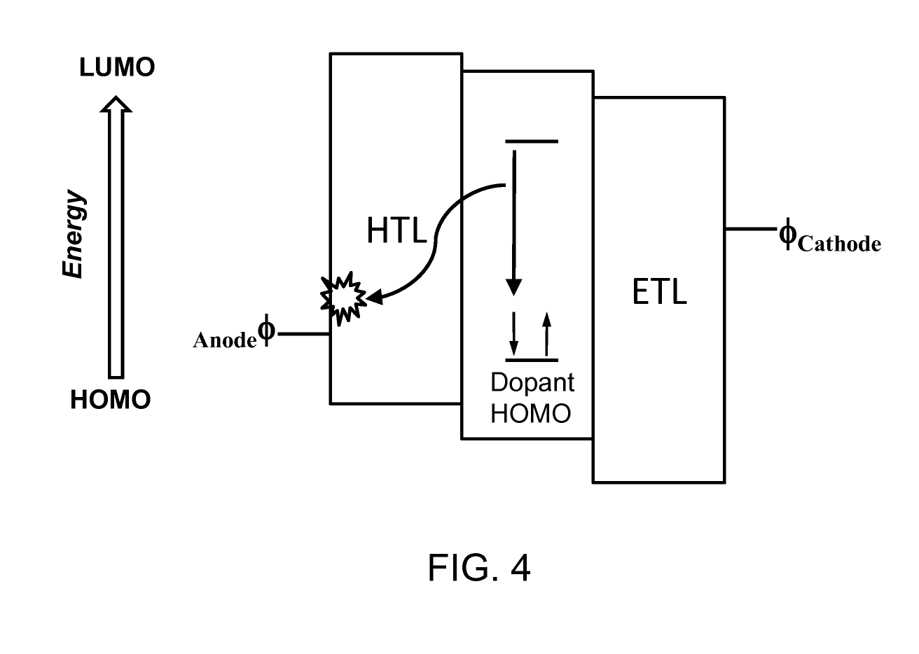

Without confinement to one specific theory, it is believed that advantageously, enhanced metal-ligand bond stability of the new compositions will lead to improved operational stability of OLED devices when used within the device light emitting layer. Support of enhanced metal-ligand stability is indicated by Density Functional Theory (DFT) calculations of the metal-ligand bond enthalpy of dissociation for new compositions. This represents the energy required to cleave the metal-ligand bond. Higher bond dissociaton energies indicate enhanced bond stability. As indicated in FIGS. 1-3, there are several steps in the process. In computational studies, the specific energy states associated with each step were considered for the bond dissociation energy calculations of various embodiments of the instant compositions using computational software tools provided by Schrödinger, LLC of Cambridge, Mass., USA. Results were obtained using the Schrödinger Materials Science Suite (MSS) (Version 1.4). Optimization of the geometries and calculations of atomic charges and ligand dissociation energies were carried out using the Jaguar Density Functional Theory (DFT) package (Version 8.4)2 using the M063 and the B3LYP4,5 hybrid density functionals. The Pople double-ζ polarized basis set, 6-31 G**, 6 representing the Pt and Ir core electrons by effective core potentials7 (designated LACVP**) was used in these calculations.

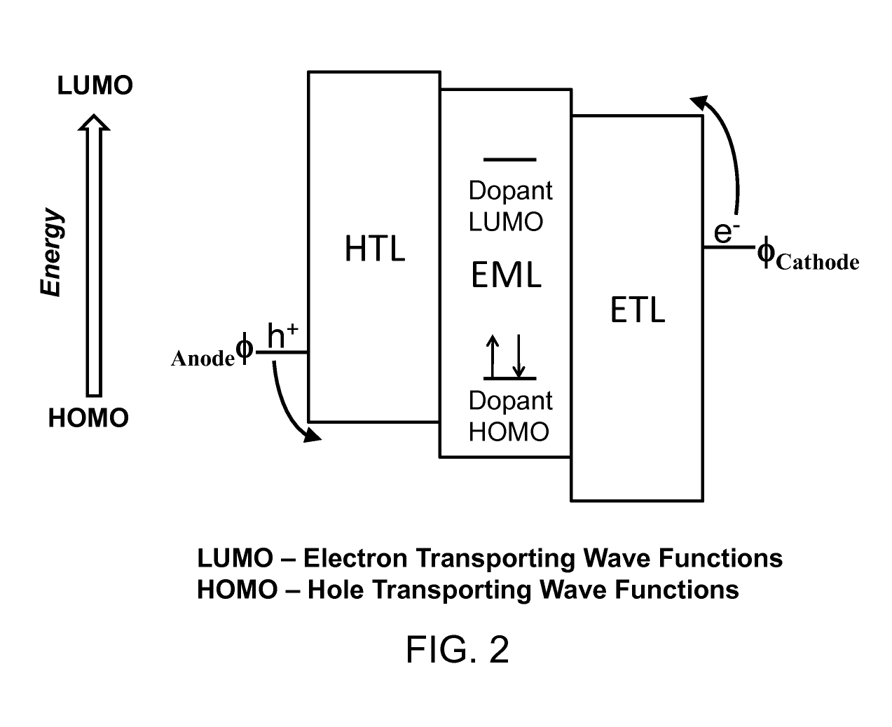

FIG. 2 illustrates the simultaneous injection of holes and elections. However, the calculated reorganization energy for holes and electrons for the instant new class of emitter compositions shows an important difference. The hole-reorganization energy is roughly half the electron reorganization energy indicating a preference to operate as hole-carriers, as set forth in TABLE 1. For the reference material, Tris(1-phenylisoquinoline) Iridium, also referred to herein as Ir(1-piq)₃, the hole reorganization energy is slightly lower than the electron reorganization. Based on this information, there is a high probability that the mechanism for Triplet Exciton formation and subsequent phosphorescent light emission involves an initial hole-injection step to form the radical cation as shown in Scheme 1. It is important to note that the HOMO levels for the new emitters shown in TABLE 1 are consistent. This is indicative of significant HOMO character on the metal center.

TABLE 1
Electronic and Transport Properties of Emitter Materials.

| | Hole | Electron | | |
|---|---|---|---|---|
| | Reorganization | Reorganization | LUMO | HOMO |
| Emitter | Energy (eV) | Energy (eV) | (eV) | (eV) |
| Inv. 1 | 0.08 | 0.16 | −2.53 | −5.44 |
| Inv. 2 | 0.07 | 0.15 | −2.73 | −5.44 |
| Ir(1-piq)₃ | 0.07 | 0.09 | −2.71 | −5.47 |

HOMO = highest occupied molecular orbital
LUMO = lowest unoccupied molecular orbital

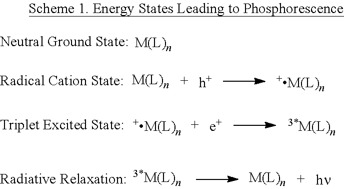

It is known that a major degradation pathway in OLED devices is homolytic bond cleavage followed by radical addition to a neighbor. Using DFT simulations, the homolytic metal-ligand dissociation energies (LDE) were estimated in order to evaluate the relative stability of the OLED emitter materials. For clarity, the specific bond dissociations evaluated are represented in Scheme 2.

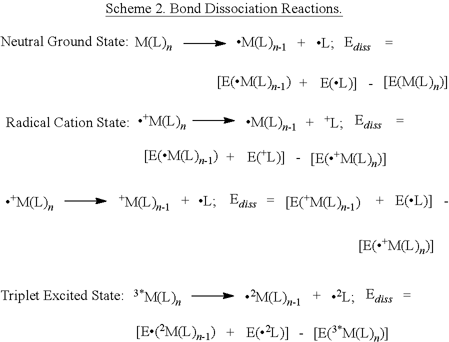

A summary of the calculated results are provided in TABLE 2. The data indicates no significant difference in the LDE for the neutral and Triplet states. However, a significant bond energy advantage is indicated for the Applicant's new class of emitter materials in the charged cationic state compared to the reference complex. Both calculation methods used show that the metal-ligand bond energies for Exemplary Compositions 1 and 2 (FIGS. 6 and 7A are >22 kcal/mol higher than the Iridium complex. This has major implications in terms of the ability to design devices for improved stability. As previously indicated, the predicted pathway to phosphorescent light generation occurs through an initial hole-injection step to form the radical cation. Therefore the new class of emitter materials could provide a significant advantage in device lifetime based on the increased stability of emitter materials in the highly concentrated radical cation state. Although the lower metal-ligand bond energy in the Triplet excited state for all emitters will still pose a challenge, kinetics favor influence of the radical cation state on device stability. The very short lifetime of Triplet Excitons dictates that the concentration will be orders of magnitude lower than the highly concentrated and more stable cation state. Increased stability in the radical cation stale provides the opportunity to leverage unique device designs that promote exposure of the novel emitters to a high concentration holes for improved stability. Improved device lifetime has been reported for phosphorescent OLED devices by using a graded dopant concentration profile for emitters with the higher concentration positioned closer to the hole injection side. Based on the DFT predicted advantage for the new class of emitters in the radical cation state, an even greater effect on device lifetime could be expected.

TABLE 2
Bond Dissociation Energies (kcal/mol)

| | M06/LACVP | | | B3LYP/LACVP | | |
|---|---|---|---|---|---|---|
| Emitter | Neutral | Cation | Triplet | Neutral | Cation | Triplet |
| Inv. 1 | 105.32 | 111.76 | 53.45 | 95.62 | 105.55 | 45.36 |
| | | 123.76 | | | 115.4 | |
| Inv. 2 | 106.48 | 111.9 | 58.21 | 96.69 | 105.49 | 50.24 |
| | | 121.69 | | | 113.23 | |
| Ir(1-piq)₃ | 107.55 | 76.65 | 60.89 | 98.69 | 83.52 | 50.31 |
| | | 97.25 | | | 88.29 | |

Certain embodiments of the invention, which use strategic substitution of the heterocyclic pyridyl group (including formation of fused rings), establish very high phosphorescence quantum efficiency compared to complexes with unsubstituted simple diaryl-amine ligands, such as dipyridylamine. The complex Pt(dpa)₂ (dpa=dipyridylamine) was prepared and used as a reference for photoluminescence quantum efficiency measurements. U.S. Pat. No. 7,063,901, the disclosure of which is incorporated herein by reference, discloses a general structure of a ligand with simple unsubstituted heterocyclic rings coordinated to a transition metal.

In certain embodiments, the instant emitter compositions are established through deprotonation of the coordinated diaryl-amine ligands. The resulting negative charge on the chelating ligand is delocalized between the bonding nitrogen atoms. Stabilization of the metal-ligand bonds is enhanced through the charge delocalization. To the best of the Applicant's knowledge, the ligands used for Exemplary Compositions 1-7 (FIGS. 6-7F) have not been disclosed previously for transition metal complexes.

### EXAMPLES

### Example 1

### Method of Preparation

In a general reaction, 3 mmol of the Pt complex K₂PtCl₄ was weighed out and transferred to a reaction flask. High purity water (8 mL) was then added to the flask and the solution stirred to dissolve the Pt salt. While stirring, 40 mL of 2-ethoxyethanol was added followed by the addition of the solid diaryl-amine ligand (6 mmol). An additional 5 mL of the solvent was used to rinse down any remaining ligand After purging the flask with nitrogen, the flask was sealed with a Rodavise cap (a condenser with a nitrogen bubbler can also be used).

The reaction was heated (75-80° C.) in an oil bath. After 24-40 hours, the heat was removed and the reaction flask allowed to cool to room temperature. The solvent was removed using a rotary evaporator. To the solid product mixture, 50 mL of acetone was added followed by 50 mL of H₂O. A slight excess of KOH dissolved in 20 mL of water was added to promote deprotonation. After stirring at room temperature for at least 1 hour, the solvent was reduced and additional H₂O was added to dissolve the salts and promote product precipitation. The product was collected by filtering using a medium porosity fritted funnel and allowed to air dry. (Alternatively, drying in vacuo would be acceptable.) Characterization of the product was carried out primarily using mass spectroscopy.

### Example 2

### Photoluminescence Measurements

Toluene solutions of Exemplary Compositions 1 and 2 (FIGS. 6 and 7A) and the reference emitter Pt(dpa)₂ were sparged with nitrogen prior to photoluminescence measurements. Absorption spectra were first obtained to determine the best excitation wavelength. A comparison of the measured solution quantum efficiencies from the photoluminescence measurements are provided in TABLE 3.

TABLE 3
Quantum Efficiency (QE) Data

| Material | QE |
|---|---|
| Inv. 1 | 0.77 |
| Inv. 2 | 0.52 |
| Pt(dpa)₂ | 0.16 |

The observed significant increase in phosphorescence QE for Exemplary Compositions 1 and 2 over the reference base structure clearly demonstrate the influence of strategic substitution. It is particularly noteworthy that the QE for Exemplary Composition 1 is very high for a red phosphorescent emitter. By comparison, QE data reported on the most referenced red cyclometalated emitter material, Ir(1-piq)₃, along with the mixed ligand complexes Ir(1-piq)₂(py) and Ir(1-piq) (py)₂, ranged from of 0.37 to 0.45. These results are quite unexpected and contradict the teachings of certain patents on cyclometalating complexes that indicate to achieve high QE for metal complexes the formation of a metal-carbon bond is required. Specific examples of patents containing such teachings include U.S. Pat. Nos. 6,830,828 and 6,902,830, the disclosures of which are incorporated herein by reference.

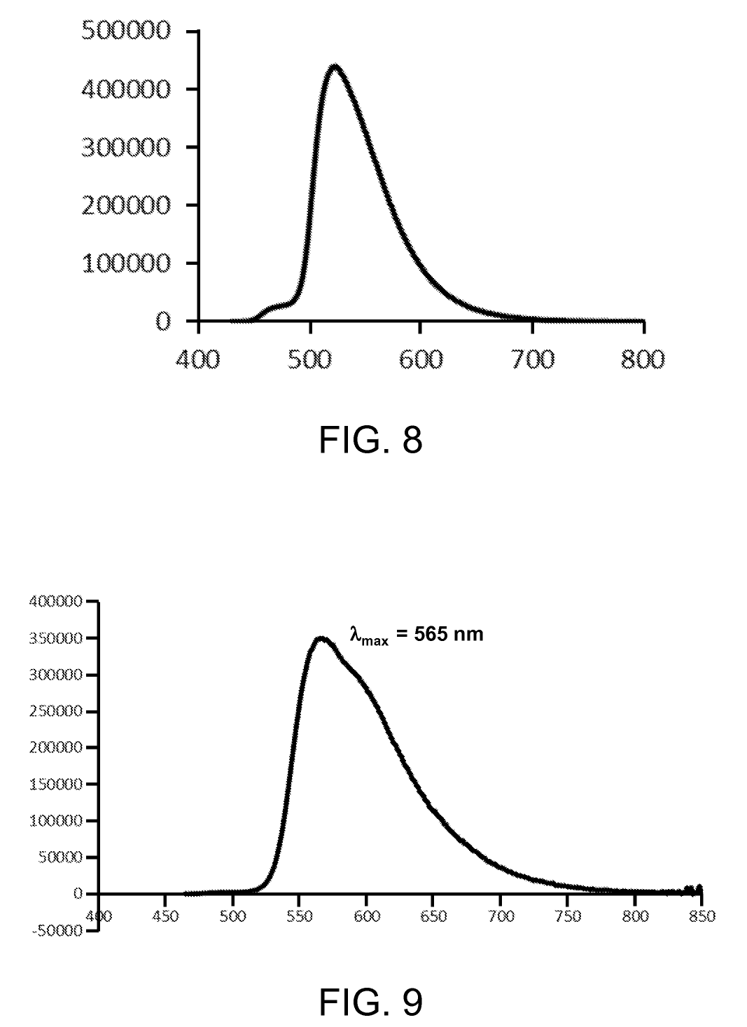

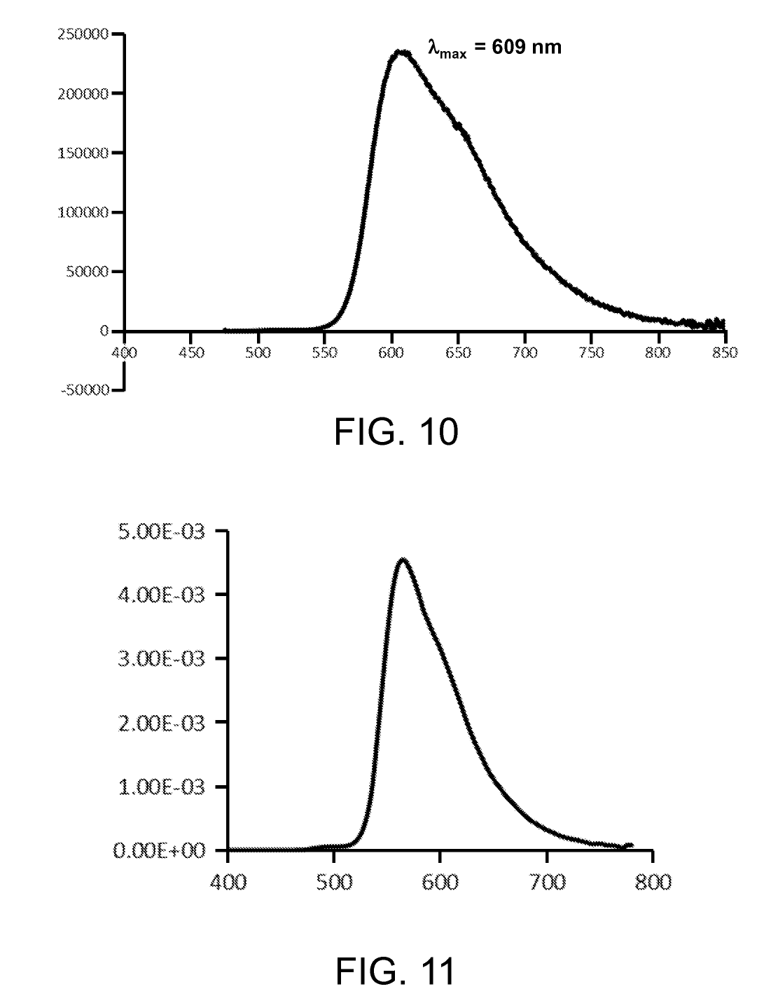

The photoluminescence spectra of the reference complex Pt(dpa)₂ and Exemplary Compositions 1 and 2 are shown in FIGS. 8, 9, and 10, respectively.

The spectra illustrate another unique feature of the instant phosphorescent emitters. As indicated previously herein, phosphorescence emission originates from the triplet manifold of Excitons. Typically the triplet energy of a molecule is dominated by the moiety which has the lowest triplet energy in an isolated state. However the photoluminescence data for Exemplary Composition 1 indicate the Triplet energies of the pyridyl and isoquinoline groups are apparently mixed, providing a final Triplet energy that falls between the isolated states. Without wishing to be bound to any particular theory, the Applicant believes that this apparent triplet energy averaging can be assigned to the charge delocalization between the groups.

### Example 3

### Device Fabrication

A glass substrate coated with about a 21.5 nm layer of indium-tin oxide (ITO), as the anode, was sequentially washed in a commercial detergent, rinsed in deionized water, rinsed with acetone, and exposed to an oxygen-plasma for about 1 min. Over the ITO, a 10 nm thick hole-injecting layer (HIL), LG-101, manufactured and sold by LG Chem Corporation of Seoul, South Korea, was vapor deposited. Next, a layer of a Hole Transporting Material, N,N′-Di(1-naphthyl)-N,N′-diphenyl-(1,1′-biphenyl)-4,4′-diamine (NPB) was deposited to a thickness of 35 nm. A 40 nm light-emitting layer (LEL) comprising a carbazole host and Exemplary Composition 1 (18%) was then deposited. An electron-transporting layer corresponding to 550 nm of 2,2′,2″-(1,3,5-Benzinetriyl)-tris(1-phenyl-1-H-benzimidazole) (TPBi) was vacuum-deposited followed by 0.5 nm of the electron-injecting layer lithium fluoride. Finally, 150 nm layer of aluminum was deposited to form a cathode layer. The electroluminescence spectrum recorded from the device is shown in FIG. 11. The spectral features were consistent with the photoluminescence spectrum. The luminous yield for the non-optimized device was very high for the recorded CIE coordinates (TABLE 4).

TABLE 4
OLED Device Data

| Luminous Yield | |
|---|---|
| cd/A | CIEx, y |
| 35 | 0.501, 0.494 |

It is therefore apparent that there has been provided, in accordance with the present disclosure, phosphorescent emitting compositions, and light emitting diodes comprised of such compositions. Having thus described the basic concept of the invention, it will be apparent to those skilled in the art that the foregoing detailed disclosure is intended to be presented by way of example only, and is not limiting. Various alterations, improvements, and modifications will occur to those skilled in the art, though not expressly stated herein. These alterations, improvements, and modifications are intended to be suggested hereby, and are within the spirit and scope of the invention.

I claim:

1. A light emitting composition comprised of a central platinum group transition metal and a bidentate ligand comprised of at least one fused pyridyl group forming a six membered ring complex.

2. The composition of claim 1, wherein the platinum group transition metal is selected from the group consisting of platinum, palladium, iridium, rhodium, ruthenium, and osmium.

3. The composition of claim 1, wherein the composition has the structure: 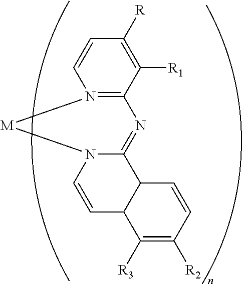
and wherein R, R₁, R₂, and R₃ are selected from hydrogen, an alkyl group, or an aryl group and n=1, 2, or 3.

4. The composition of claim 1, wherein the platinum group transition metal is platinum.

5. The composition of claim 4, wherein the composition has the structure: 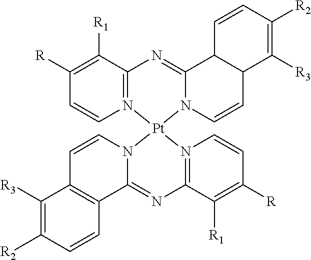
and wherein R, R₁, R₂, and R₃ are selected from hydrogen, an alkyl group, or an aryl group.

6. The composition of claim 5, wherein the composition has the structure:

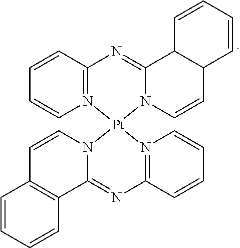

7. The composition of claim 5, wherein the composition has the structure:

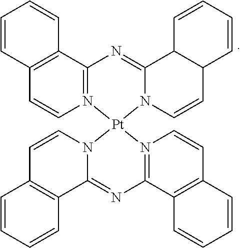

8. The composition of claim 5, wherein the composition has the structure:

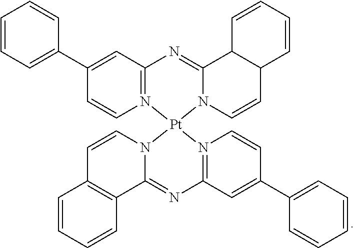

9. The composition of claim 5, wherein the composition has the structure:

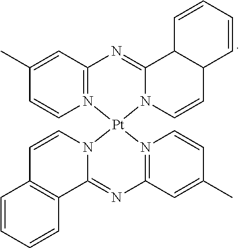

10. The composition of claim 5, wherein the composition has the structure:

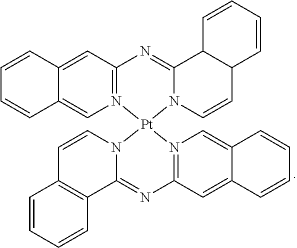

11. The composition of claim 5, wherein the composition has the structure:

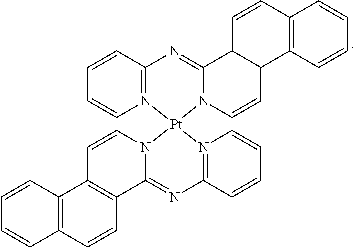

12. The composition of claim 5, wherein the composition has the structure:

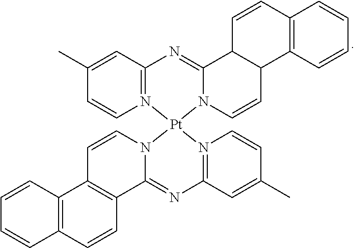

13. An OLED device comprising a light emitting layer including a light emitting composition comprised of a central platinum group transition metal and a bidentate ligand comprised of at least one fused pyridyl group forming a six membered ring complex.

14. The OLED device of claim 13, wherein the platinum group transition metal is selected from the group consisting of platinum, palladium, iridium, rhodium, ruthenium, and osmium.

15. The OLED device of claim 13, wherein the composition has the structure: 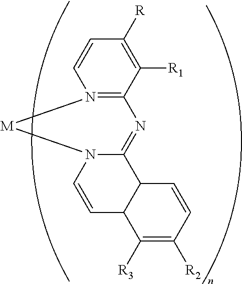
and wherein R, R₁, R₂, and R₃ are selected from hydrogen, an alkyl group, or an aryl group and n=1, 2, or 3.

16. The OLED device of claim 13, wherein the platinum group transition metal is platinum.

17. The OLED device of claim 16, wherein the composition has the structure: 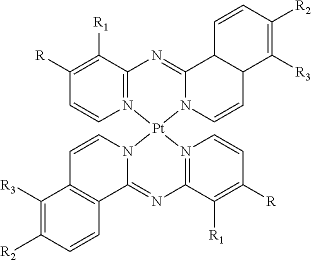
and wherein R, R₁, R₂, and R₃ are selected from hydrogen, an alkyl group, or an aryl group.

18. The OLED device of claim 17, wherein the composition has the structure:

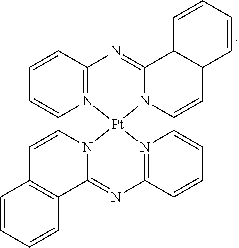

19. The OLED device of claim 17, wherein the composition has the structure:

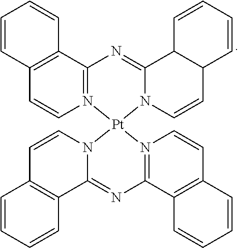

20. The OLED device of claim 17, wherein the composition has the structure: [chemical structure]
